(19) United States
(12) Patent Application Publication
(10) Pub. No.: US 2007/0172745 A1
(43) Pub. Date: Jul. 26, 2007

(54) Evanescent wave assist features for microlithography

(76) Inventor: Bruce W. Smith, Penfield, NY (US)

Correspondence Address: HISCOCK & BARCLAY, LLP, 2000 HSBC PLAZA, 100 Chestnut Street, ROCHESTER, NY, 14604-2404, US

(21) Appl. No.: 11/627,750

(22) Filed: Jan. 26, 2007

Related U.S. Application Data
(60) Provisional application No. 60/762,478, filed on Jan. 26, 2006.

(51) Int. Cl. G03C 5/00; G03F 1/00

(52) U.S. Cl. 430/5; 430/322; 430/323; 430/324

(57) ABSTRACT

A method for improved imaging performance of a microlithography photomask is described. By providing sub resolution evanescent wave assist features in regions surrounding a main photomask feature, the coupling of the evanescent energy from these features can add to the transmission efficiency of the main feature. The photomask comprises a transparent substrate support member having at least a first and second surface, wherein said first surface is smooth and said second surface is patterned with a plurality of grooves; a film coating disposed over said plurality of groves, wherein said film coating has one or more openings.

### CROSS-REFERENCE TO RELATED APPLICATIONS

This application claims priority from U.S. Provisional Patent Application Ser. No. 60/762,478, filed Jan. 26, 2006, the entire disclosure of which is hereby incorporated by reference herein.

### FIELD OF THE INVENTION

The present invention relates to the field of microlithography for processing of integrated circuit devices, particularly photolithographic masking and imaging.

### BACKGROUND OF THE INVENTION

Methods of photomask pattern layout and optimization for integrated circuit microlithography are used to optimize the image performance of small geometries. These small geometries include lines, spaces, and contact holes (or vias) of various densities and sized on the order of 0.25×lambda/NA to 1.0×lambda/NA at the wafer level (or larger by a magnification factor M at the mask level). Various methods of pattern enhancement have been employed to increase the image fidelity of such patterns, including the use of phase shift masking approaches and optical pattern correction. A summary of such approaches is given for example in [Microlithography: Science and Technology, J. R. Sheats and B. W. Smith, eds., Marcel Dekker, NY, 1998].

In photolithography, a photomask is the object of the optical imaging system. This photomask is illuminated with short wavelength UV radiation by means of lamp or laser source and an illumination optical system. The diffraction information is propagated through the far-field toward a projection lens, which relays in to the wafer plane as an intensity image. This intensity image is then recorded in a photoresist film, which is then used as protective resistant layer for etching or implant operations. The photomask is comprised of a support substrate, generally fused silica. The object pattern exists as geometry etched into a dielectric media, known as a masking film, most commonly chromium-oxi-nitride, a composite graded film of chromium oxide (Cr₂O₃) and chromium nitride (CrN). Other materials are also employed as a masking film, including oxides and nitrides of refractory metals, often combined with oxides and/or nitrides of silicon.

According to classical optics theory, as geometry is placed on the mask that is sub-wavelength in size, the far field diffraction pattern includes only zero order light with no pattern information. All other diffraction energy is evanescent, or bounded in the surface of the mask and decaying rapidly at small distances from the feature. If an approach was possible to increase the pattern information beyond that which is carried by the zero order, an improvement in resolution would be possible.

The transmission properties of small wavelength-scale arrays and grids has been studied and published in various references. [Rotten, L. C. et al., International Journal of Infrared and Millimeter Waves, vol. 6, No. 7, pp. 511-575, (1985); Lezec and Thio, Optics Express, Vol. 12, No. 16, pp 3629-3651 (2004); T. Thio et al., Optics Letters, vol. 26, no. 24, pp. 1972-1974 (2001); T. W. Ebbesen, H. J. Lezec, H. F. Ghaemi, T. Thio, P. A. Wolf, Nature, 391, 667-669 (1998)]. The transmission enhancement for light traveling through arrays of sub-wavelength metal holes and line arrays have been shown to be surface plasmonic effect in U.S. Pat. No. 6,052,238 to Ebbesen, et. al., entitled, “Near-field Scanning Pptical Microscope having a Sub-Wavelength Aperture Array for Enhanced Light Transmission,” U.S. Pat. No. 6,236,033 to Ebbesen, et. al. entitled, “Enhanced Optical Transmission Apparatus Utilizing Metal Films having Apertures and Periodic Surface Topography,” and U.S. Patent Application No. 2003/0173501, to Thio, et. al., entitled, “Enhanced Optical Transmission Apparatus with Improved Aperture Geometry,” each of which are incorporated by reference in their entirety.

Through the structuring of periodic surface topography, light incident on the surface of the metal interacts with a surface plasmon mode to increase the transmission efficient of sub-wavelength features. U.S. Pat. No. 6,649,901 to Thio, et. al., entitled Enhanced Optical Transmission Apparatus with Improved Aperture Geometry,” describes a metal plasmonic effect by optimizing the geometry and the relationship of the geometry in a metal film. The mechanism of surrounding apertures by periodic surface corrugations has been suggested for use as an enhancement approach for wavelength-selective optical filters, spatial optical filters, light collectors, and near-field scanning optical microscope probes. A read-write head for optical storage has also been described using periodic surface structures in metal films in U.S. Pat. No. 6,834,027 to Sakaguchi, entitled, “Surface Plasmon-Enhanced Read/Write Heads for Optical Data Storage Media.” Improvements on the use of metal film patterns has been also been described U.S. Pat. No. 6,285,020 to Kim, entitled. “Enhanced Optical Transmission Apparatus with Improved Inter-Surface Coupling.” Additionally, a variety of imaging techniques are known in the art and described in U.S. Pat. No. 7,115,355 to Schmidt, entitled “Fabrication of Sub-Wavelength Structures,” U.S. Pat. No. 7,144,685 to Mizutanii, et. al., entitled “Method for Making a Pattern Using Near-Field Light Exposure Through a PhotoMask,” and U.S. Patent Application Publication No. 2005/0064303 to Yamada et. al., entitled, “Near-Field Light Generating Structure, Near-Field Exposure Mask, and Near-Field Generating Method,” all of which are incorporated by reference in their entirety. The application of these approaches are not practical for photolithography because the thin film masking materials used in a photomask are not metallic type films. Instead, they are dielectric nitride and oxide thin film materials.

An approach to enhance the transmission of sub-wavelength features patterned in a dielectric photomask film through the coupling of the fields generated from geometry close to these apertures is desired. Since the photomask films are not metallic, a surface-plasmonic effect as described in the prior art does not offer a solution to the problem. The object of the invention is to overcome the limitations of the prior art for the application of sub-wavelength features to improve the transmission efficiency of small apertures in dielectric photomask films. A method utilizing the coupling of evanescent energy into photomask geometry is desired.

### SUMMARY OF THE INVENTION

The invention comprises, in one form thereof, a method of using small sub-resolution features in a photomask film (spaced closely enough so that the resulting pitch is close to or below the illumination wavelength), placed in surrounding regions of an intended feature, to create evanescent waves that assist the imaging of the main feature. These assist features are referred to as evanescent wave assist features (EWAFs).

An advantage of the present invention is that the transmission efficiency of small apertures in dielectric photomask films will be improved.

### BRIEF DESCRIPTION OF THE DRAWINGS

The present invention is disclosed with reference to the accompanying drawings, wherein:

FIG. 1 is an embodiment of the invention showing EWAFs on opposite sides of a main feature;

FIG. 2 shows the resulting impact on imaging of EWAFs;

FIG. 3 shows an embodiment of the invention with one pair of EWAFs inside a main feature opening;

FIG. 4 shows an embodiment of the invention with EWAFs on the back side of a mask;

FIG. 5 shows a near field transmission for a chromium oxide film;

FIG. 6 shows a near field transmission for a chromium nitride film;

FIG. 7 shows a near field transmission for a tantalum nitride film;

FIG. 8 shows a near field transmission for a chromium film; and

FIG. 9 shows a far field transmission for a chromium oxide film.

Corresponding reference characters indicate corresponding parts throughout the several views. The examples set out herein illustrate several embodiments of the invention but should not be construed as limiting the scope of the invention in any manner.

### DETAILED DESCRIPTION

Evanescent waves are by classification elusive, as they are defined by their rapid decay and ability to escape measurement. When illuminating a small aperture in an opaque screen, it is well understood that the far-field diffraction pattern propagates as the Fourier Transform of the opening. As the aperture size decreases, a propagating “point spread function” possesses a correspondingly larger aperture of propagation. As the aperture is made smaller than half-wavelength, the corresponding wave vector in the direction of propagation (z) falls to zero and then becomes purely imaginary. This energy does not propagate but remains bound to the surface or medium interface. In essence, the lowest spatial frequency of the aperture (the DC component) is transmitted and all higher frequencies remain in the z-plane where no structural detail of the aperture is propagated. In the case of a collection of apertures, when the resulting diffraction order angles reach unity, they are described as evanescent or surface bound. This is a near field implication to the far field effect as the evanescent field never escapes the sub-wavelength region of the surface for propagation to the far field. As a the pitch of the collection of apertures approaches the illuminating wavelength (irregardless of aperture size or spacing), only the zero order escapes to the far field. All other diffraction orders are confined to the near field as evanescent to the surface, leading to what can be referred to as a “zero-order grating.” Reference can be made to [B. W. Smith, D. E. Ewbank, SPIE Optical Microlithography XV, vol. 4691 (2002)] for further discussion on zero-order gratings, the entirety of which is incorporated herein by reference.

The scatter distribution of a sub-wavelength aperture includes energy propagating into free-space as well as surface bound evanescent energy. This total surface energy is the superposition of evanescent waves emanating from the aperture. The diffracted field of a zero-order grating includes surface bound evanescent energy as a collection of the evanescent waves emanating from each aperture. The question arises as to whether these evanescent waves can interfere in such a way as to create a composite superpositioning, resulting in constructive and destructive effects, as does the interference of a conventional propagating electric field. Leviatan investigated whether the diffraction of evanescent waves could lead to propagating waves just as diffraction of plane waves can generate evanescent waves as discussed in [Y. Leviatan, IEEE Trans. Microwave Theory and Techniques, 36, 1 (1988)], incorporated herein by reference. By studying the effect of the lateral separation of two sub-wavelength apertures separated in the near field for microwave application, it was discovered that the lateral shifting between these apertures could lead to a harmonic coupling resonance with maximum enhancement at regular spacing intervals.

Lezec and Thio presented an expansion of the phenomena to describe the enhancement observed as an opening in a metal film over glass is surrounded by periodic grooves, as discussed in [H. Lezec and T. Thio, Optics Express, 16, 3629 (2004)], incorporated herein by reference. These periodic sub-wavelength grooves create evanescent waves that are confined to the surface of the metal film. A composite diffracted evanescent wave is formed as the full surface wave energy traveling toward the opening is a superposition of these surface waves.

In the present invention, as a small feature on a photomask sized near the wavelength of radiation is illuminated, an evanescent wave is created which travels along the surface of the substrate in the direction perpendicular to the long dimension of the feature. The amplitude of the wave decays as it moves away from the feature, reducing in amplitude exponentially as the distance traveled increases. If more than one feature is placed on the photomask, of equivalent or similar size, the evanescent field will interfere constructively to enhance the total evanescent field intensity, which is greater than the intensity of a single feature alone. As the number of features increases, the total intensity increases until a point is reached where no additional effect is produced with additional features. This will occur as the scale length of all features approaches the decay length of the total evanescent wave, which is between three and ten wavelengths.

If the evanescent features are place in close proximity to a larger open feature, the evanescent wave energy will cause an increase in the radiation intensity in the larger feature, if this feature is greater than the resolution limitation of the wavelength of radiation used to illuminate it. Additionally, if the sub-resolution features are created so that they are not transmissive in a dark masking region or not absorbing in a clear field region, they will enhance the intensity through a hole in a dark region or conversely around a line in a clear region. The result is an increase in the contrast of the larger feature compared to that that would result if the sub-resolution features were not present.

A dielectric photomask film, also referred to as an absorber layer, covers the evanescent features that are patterned into the mask substrate, burying them and preventing any propagation through the film. When the features and their period are sub-wavelength, a zero-order diffraction grating is formed, forcing all other energy to be evanescent in the glass-thin film-n interface. As the period becomes larger than the illuminating wavelength, the evanescent field decreases but is still present as long as the feature size remains sub-wavelength. Under plane wave illumination, each feature launches an evanescent wave which will travel along this interface perpendicular to the main space opening. The amplitude of these evanescent waves decreases exponentially with distance but they will interfere with each other during their travel. If added constructively, the total composite field can increase with each successive interaction. If this coupling wave then encounters an opening, the amount of energy that propagates through that opening is modulated based on the phase interference between the composite fields. The preferred structures of these evanescent features are grooves or corrugations in the transparent mask support substrate. This substrate is more commonly glass or fused silica but may also be a fluoride material such as magnesium fluoride or calcium fluoride.

The sub-resolution features are optimized for their spacing and sizing so that the interference of the composite evanescent wave is constructive. The increased intensity in the main feature clear mask region (such as a hole or a space) in a dark field mask is diffracted to form an image of the feature, which is imaged through a projection lithography system. This is also true for dark features (lines or islands) in a clear field mask. As the main feature approaches M×0.25×lambda/NA to M×1.0×lambda/NA, the effects are most pronounced as these features become difficult to print under normal conditions without the assist features.

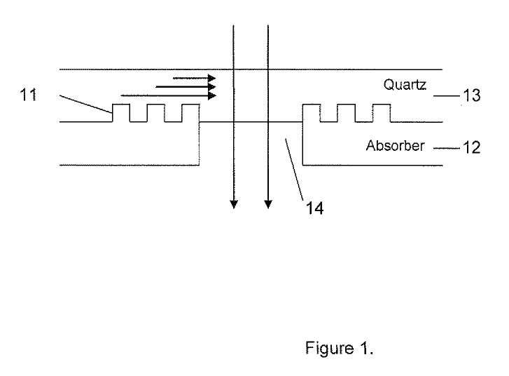

Referring now to FIG. 1, there is shown an example of a mask layout using sub-resolution EWAFs 11 for enhancement, of a size approximately equal to one half of the exposing radiation wavelength, lambda/2, spaced one wavelength, lambda, apart. The features are etched into a fused silica (also referred to as synthetic quartz) mask substrate 13. An absorber film 12 of a metal, dielectric, or composite material is used to cover features 11. The absorber film 12 may be for example chromium nitride, chromium oxide, a chromium-oxi-nitride binary masking film, or one of many choices for an attenuated phase shift masking film, such as molybdenum-silicon-oxide, tantalum-silicon-nitride, or others. The absorber film 12 covers features 11 to create a main feature opening 14. In one dimension, main feature opening 14 represents a space, and in two dimensions main feature opening 14 represents a space represents a contact hole. The region comprising the space is also referred to as the clear region. The region not comprising the space feature is often referred to as the dark or line region

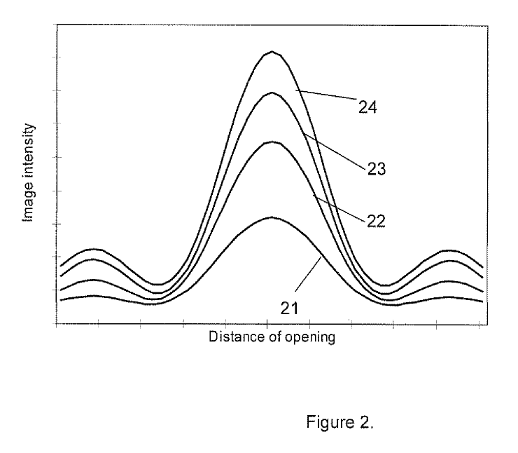

FIG. 2 illustrates how one or more pairs of EWAFs enhance the imaging of a space or contact hole. Shown here is a main feature opening that is approximately M×0.43×lambda/NA in size with a pitch to the next main feature opening of M×1.29×lambda/NA, with EWAF features of approximately lambda/2n in size and spaced with a pitch of lambda, where n is the refractive index of the region surrounding the EWAF feature. In two directions, this opening represents a contact hole. The transmission with no EWAFs 21 is shown possesses the lowest image intensity. When transmission is increased with two pairs of EWAFs 22, the image intensity increases. Further image intensity increase with transmission with three pairs of EWAFs 23, and with four pairs of EWAFs 24. The resulting increase in transmitted intensity results in an increase in contrast of the opening, and an increase in resolvability.

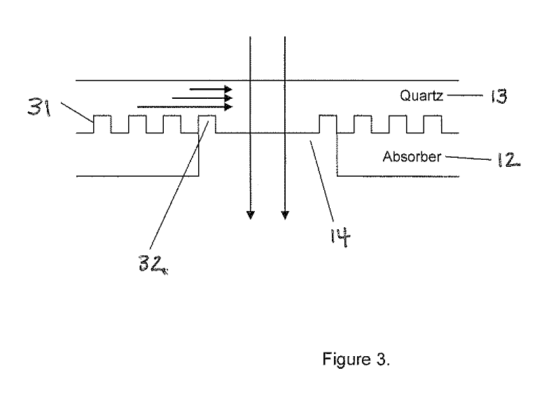

In FIG. 3, an alternate example of the invention is shown where an EWAF feature 32 is added to the grouping 31 and is formed in the main feature opening 14, which is phase shifted compared to the main opening 14. The substrate 13 supports the absorber layer 12 as in other examples. The change in phase of the electric field in this opening results in further increase in the contrast of the main feature.

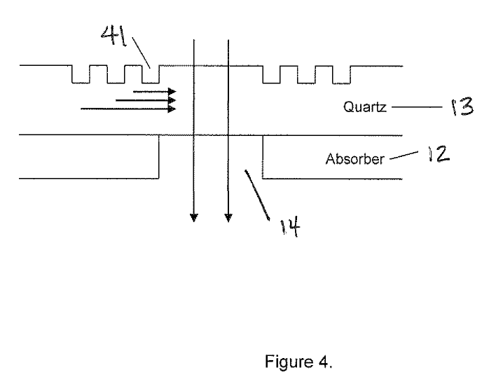

In FIG. 4, the EWAF features 41 are placed on the back side of the mask substrate 13, which also act to create an evanescent field that will increase the intensity in the main feature opening 14. The absorber layer 12 is coated on the opposite side as the EWAF features.

The evanescent wave enhancement effect described here, and attributed to the use of EWAF features, is not limited to hole patterns or openings. A dark line feature or island can also be improved if the EWAF features are added behind the line. In this case, FIGS. 1, 3, and 4 represent the dark feature that bounds a clear region,

The layout an integrated circuit photomask requires computer based design tools and programs. To optimize the placement of EWAFs and main features for use on a photomask, certain design rules and parameters must be chosen, including for example the position, sizing, and shaping of EWAFs with respect to the integrated circuit patterns on each photomask level. Such computer aided design (CAD) systems that employ layout design rules can be adapted for automatic optimization and placement of EWAFs within the photomask for resolution enhancement of integrated circuit patterns.

The enhancement of the transmission of radiation through an opening can be a result of the use of grooves or corrugations placed between the photomask absorber and the mask glass substrate when the absorber is metallic, dielectric, or semiconductor. In the case of a metallic film, this may for instance be chromium. In the case of a dielectric absorcer, this may for instance be an oxide, a nitride, or a fluoride. In the case of a semiconductor, this may be silicon, for instance.

### EXAMPLE 1

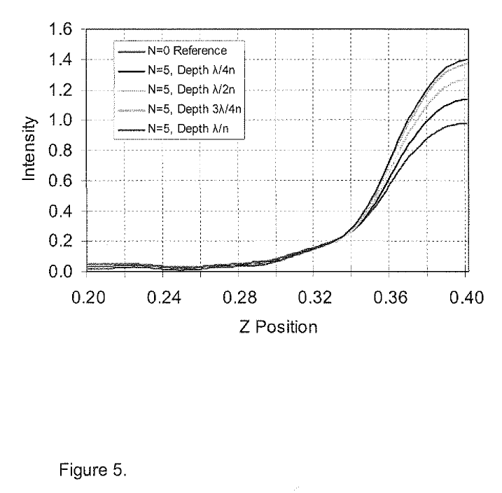

FIG. 5 illustrates the effect that EWAFs of the present invention have on a chromium oxide film for 1:3.8 duty ratio 45 nm contacts on a 215 nm pitch (1×) and N=±5 EWAFs using 62 nm EWAF(λ/2n) of various depths from lambda/4n to lambda/n compared to no EWAF (reference). The goal is to improve the transmission through the contact opening. The enhancement in transmission is 42.6% over the case with no EWAF features.

### EXAMPLE 2

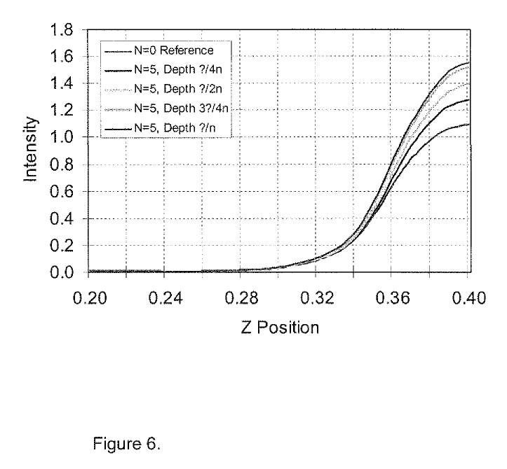

FIG. 6 illustrates the effect that EWAFs of the present invention have on a chromium nitride film for 1:3.8 duty ratio 45 nm contacts on a 215 nm pitch (1×) and N=±5 EWAFs using 62 nm EWAF(λ/2n) of various depths from lambda/4n to lambda/n compared to no EWAF (reference). The enhancement is 42.0% over the case with no EWAF features.

### EXAMPLE 3

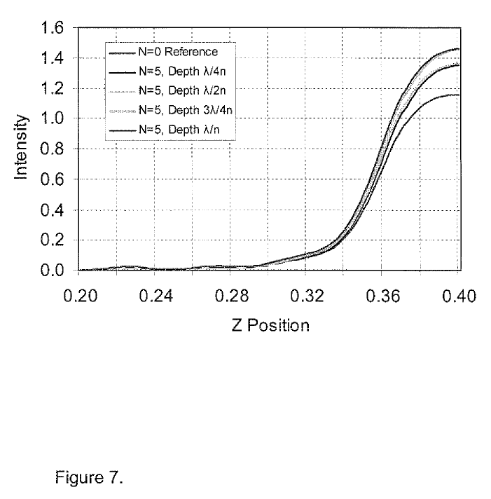

FIG. 7 shows the effect that EWAFs of the present invention have on a tantalum nitride film for 1:3.8 duty ratio 45 nm contacts on a 215 nm pitch (1×) and N=±5 EWAFs using 62 nm EWAF(λ/2n) of various depths from lambda/4n to lambda/n compared to no EWAF (reference). The enhancement is 26.4% over the case with no EWAF features.

### EXAMPLE 4

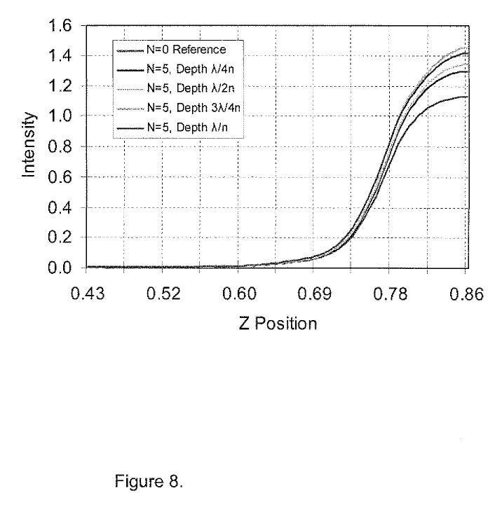

FIG. 8 shows the effect that EWAF features of the present invention have on a chromium film as an absorber for application to 1:3.8 duty ratio 45 nm contact on a 215 nm pitch (1×) and N=±5 EWAFs using 62 nm EWAF(λ/2n) with various depths from lambda/4n to lambda/n compared to no EWAF (reference). There is a 28.4% gain in the near field intensity for this case.

### EXAMPLE 5

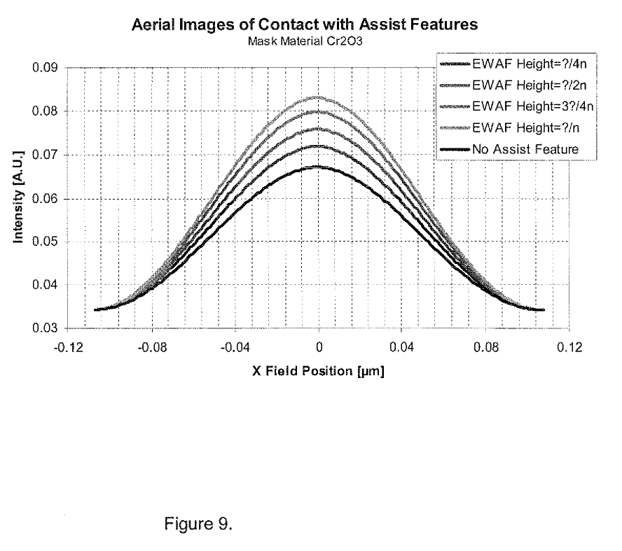

FIG. 9 is a far field plot resulting from a Cr₂O₃ absorber 45 nm contact on 215 nm pitch printed with 193 nm wavelength at 0.93 NA and 0.8ν (partial coherence) along the TE polarization axis. This plot shows the increase in the intensity at the wafer plane, which would be translated into photoresist exposure. An improvement of up to 24% is achieved using EWAFs over the standard non-assisted case.

The present invention is described above, but it is to be understood that it is not limited to these descriptive examples. The numerical values, EWAF size and spacing parameters, locations, materials, wavelength, and density may be changed to accommodate specific conditions of imaging masking, feature orientation, duty ratio requirements and the like as required to achieve high integrated circuit pattern resolution. The examples described here do not limit the application of the invention and it should be obvious to those practiced in the art that application to other wavelengths and with variations in imaging situations is possible.

I claim:

1. A photomask for projection lithography comprising:
a transparent substrate support member having at least a first and second surface, wherein said first surface is smooth and said second surface is patterned with a plurality of grooves;
a film coating disposed over said plurality of groves, wherein said film coating has one or more openings; and
wherein transmission of irradiation through said one or more openings is enhanced by evanescent coupling between said plurality of grooves and said one or more openings.

2. The photomask of claim 1, wherein said film coating comprises a dielectric material.

3. The photomask of claim 1, wherein said film coating comprises a metallic material.

4. The photomask of claim 1, wherein said film coating comprises a metallic nitride material.

5. The photomask of claim 1, wherein said film coating comprises a dielectric nitride material.

6. The photomask of claim 1, wherein said film coating comprises a dielectric oxide material.

7. The photomask of claim 1, wherein said film coating comprises a metallic oxide material.

8. The photomask of claim 1, wherein said film coating comprises an oxi-nitride material.

9. The photomask of claim 1, wherein said film coating comprises a metallic oxi-nitride material.

10. The photomask of claim 1, wherein said film coating comprises chromium.

11. The photomask of claim 1, wherein said film coating comprises chromium oxide.

12. The photomask of claim 1, wherein said film coating comprises chromium nitride.

13. The photomask of claim 1, wherein said film coating comprises chromium oxynitride.

14. The photomask of claim 1, wherein said film coating comprises a nitride chosen from the group consisting of Ta, Mo, Ti, Cr, Nb, Ru, Rh, W, Zr, and Al.

15. The photomask of claim 1, wherein said film coating comprises an element chosen from group IVA, VA, and VIA.

16. The photomask of claim 1, wherein said film coating comprises an oxide chosen from the group consisting of Ta, Mo, Ti, Cr, Nb, Ru, Rh, W, Zr, and Al.

17. The photomask of claim 1, wherein at least one of said one or more openings is square.

18. The photomask of claim 1, wherein at least one of said one or more openings is rectangular.

19. The photomask of claim 1, wherein said one or more openings includes a plurality of contact holes.

20. The photomask of claim 1, wherein said plurality of groves have a depth between about lambda/(4n) and 4lambda/n, where lambda is defined as exposing radiation wavelength and n is defined as refractive index of said transparent substrate support.

21. The photomask of claim 1, wherein said plurality of groves have a pitch of about lambda/(4n) and 4lambda/n, where lambda is defined as exposing radiation wavelength and n is defined as refractive index of said transparent substrate support.

22. The photomask of claim 1, further comprising an absorber.

23. The photomask of claim 22, wherein said absorber has a depth between about 10 to 1000 nanometers.

24. A projection lithography imaging system comprising:
an illumination system configured to produce radiation in the ultraviolet-visible spectral region;
a projection system configured to produce an image;
a photosensitized substrate to record said image;
a photomask including one or more sub-resolution features and a main feature,
wherein said photomask is configured to create an object for projection in said system; and
wherein said one or more sub-resolution features produce an evanescent wave when irradiated by said illumination system.

25. The system of claim 24, wherein said evanescent wave enhances resolution of said main feature.

26. The system of claim 24, wherein said photomask includes a pattern chosen from the group consisting of a contact hole pattern, a space pattern, a line pattern, and an island pattern.

27. The system of claim 24, wherein said photomask further includes an absorber.

28. The system of claim 27, wherein said one or more sub-resolution features are disposed between said absorber and said photosensitized substrate.

29. The system of claim 24, wherein said photomask includes a front and a back.

30. The system of claim 29, wherein said one or more sub-resolution features are disposed on said back of said photomask.

31. The system of claim 27, wherein said one or more sub-resolution features are patterned into said absorber.

32. The system of claim 24, wherein said one or more sub-resolution features are disposed within said main feature.

33. A system for computing the steps of photomask design layout including evanescent wave assist features using a computer system comprising:
a central processing unit for computation of evanescent wave assist feature placement solutions;
a memory storing computer instructions for said computation of said evanescent wave assist feature placement solutions, wherein when said computer instructions are executed on the central processing unlit, they perform a process comprising the steps of:
determining design parameters for one or more main features and one or more sub-resolution features, wherein said one or more sub-resolution features are designed to produce an evanescent wave when irradiated by an illumination source;
optimizing said photomask for resolution enhancement; and
generating evanescent wave assist feature placement solutions wherein an optimized photomask design is saved in a file which is used to create patterns on a imaged substrate.

34. The system of claim 33, wherein said design parameters are chosen from the group consisting of number, size, location, and shape.

35. The system of claim 33, wherein said optimized photomask design includes a pattern chosen from the group consisting of a contact hole pattern, a space pattern, a line pattern, and an island pattern.
